(19) United States
(12) Patent Application Publication
(10) Pub. No.: US 2024/0405015 A1
(43) Pub. Date: Dec. 5, 2024

(54) SEMICONDUCTOR DEVICE WITH ESD PROTECTION STRUCTURE AND METHOD OF MAKING SAME

(71) Applicant: HeFeChip Corporation Limited, HONG KONG (CN)

(72) Inventor: Geeng-Chuan CHERN, Cupertino, CA (US)

(21) Appl. No.: 18/336,707

(22) Filed: Jun. 16, 2023

(30) Foreign Application Priority Data
Jun. 5, 2023 (CN) 2023106588092

(51) Int. Cl. H01L 27/02; H01L 21/266; H01L 21/762; H01L 29/06; H01L 29/40; H01L 29/78

(52) U.S. Cl. CPC H01L 27/0266; H01L 21/266; H01L 21/76224; H01L 29/0619; H01L 29/401; H01L 29/7835

(57) ABSTRACT

A semiconductor device with ESD protection structure and a method of making it are disclosed. The semiconductor device with ESD protection structure includes at least one gate and source and drain regions on opposite sides of the at least one gate that constitute at least a discharging MOSFET. The gate includes first gate portions having a first dopant concentration and a second gate portion having a second dopant concentration. The first dopant concentration is lower than the second dopant concentration. The at least one first gate portions are lower portions of the gate above the edges of an active area, and the second gate portion is the remaining portion of the at least one gate other than the first gate portions.

### CROSS-REFERENCE TO RELATED APPLICATION

This application claims the priority of Chinese patent application number 2023106588092, filed on Jun. 5, 2023, the entire contents of which are incorporated herein by reference.

### TECHNICAL FIELD

The present invention relates to the field of semiconductor technology and, in particular, to an electrostatic discharge (ESD) protection device and a method of making the device.

### BACKGROUND

As integrated circuits are being increasingly miniaturized, operating at higher speeds and consuming less power, they are becoming more sensitive to electrostatic discharge (ESD) events. For this reason, integrated circuit products typically include semiconductor device with ESD protection structures.

FIG. 1 is a schematic electrical diagram of an integrated circuit employing a discharging MOSFET for ESD protection. As shown in FIG. 1, the integrated circuit includes an internal circuit 10 and the discharging MOSFET 20. The internal circuit 10 is coupled to voltage source terminal (e.g., Vdd), input and/or output (I/O) pad 30 and a ground node GND1, and the discharging MOSFET 20 is coupled between the I/O pad 30 and a ground node GND2. A gate, a source and a substrate of the discharging MOSFET 20 are usually grounded, and a high-resistance resistor is connected between the gate and the ground node GND2 for “soft ground”. A drain of the discharging MOSFET 20 is connected to the I/O pad 30. The discharging MOSFET 20 includes a parasitic transistor such as an NPN bipolar junction transistor (BJT). During operation of the integrated circuit, when an ESD voltage or current at the drain of the discharging MOSFET 20 exceeds an expected level as a result of accumulation of electrostatic charges, the parasitic transistor will be turned on to quickly discharge the ESD voltage or current to the ground. As a result, the ESD voltage will drop rapidly, and the electrostatic charge will not enter and possibly damage the internal circuit 10. The property of the parasitic transistor that causes an abrupt voltage drop is called “snap-back”.

There are two possible mechanisms for snap-back. The first mechanism is a reduction in a potential barrier between an emitter and a collector of the parasitic transistor. In this case, the drain and the source of the discharging MOSFET 20 correspond to the collector and the emitter of the parasitic transistor, respectively, and the substrate of the discharging MOSFET 20 corresponds to a base of the parasitic transistor. The reduction in the potential barrier between the emitter and the collector is due to a gate voltage which is coupled to the drain voltage via an RC circuit (including the soft-ground resistor 41 and a drain-to-gate capacitor 42). Two MOS transistors are connected in parallel to the soft-ground resistor 41 to prevent the formation of a high ESD current due to an excessive rise in the gate voltage, which may possibly cause damage to the discharging MOSFET 20. The second mechanism for the snap-back property of the parasitic transistor is forward biasing of a base-emitter junction, as mentioned in prior art patents (e.g., the U.S. Pat. No. 7,579,658 B2). In this case, in response to a collector-base junction at the drain (or referred to as a drain junction) being broken down by an ESD voltage, a current is generated in the substrate and flows through a resistor at the base of the parasitic transistor. This raises a voltage at the substrate near the base-emitter junction at the source (or referred to as a source junction), thereby turning on the parasitic transistor.

FIG. 2 is a schematic cross-sectional view of a discharging MOSFET for use in the integrated circuit of FIG. 1. Referring to FIG. 2, the discharging MOSFET 20 includes, for example, a substrate 21 and, formed on an active area of the substrate 21, a gate dielectric layer 22 and a gate 23. The active area is surrounded by a shallow trench isolation (STI) structure formed in the substrate 21, and the gate 23 overlaps the STI on both ends. As shown in FIG. 2, when the discharging MOSFET 20 is fabricated using a conventional process, a divot 201 may be present in the STI in the vicinity of the active area, making the gate dielectric layer 22 covering edges of the active area is thinner (e.g., the region shown in FIG. 2 as being encircled by a dashed oval). Due to the corner effect, a stronger electrical field will be present in those regions when a parasitic transistor in the discharging MOSFET 20 is turned on, leading to a higher ESD current at the corner of the active area than in the rest of the active area during electrostatic discharge. This tends to cause current crowding and damage to the discharging MOSFET 20. Moreover, compared to the rest of the active area, the discharging MOSFET 20 at the corner of the active area will experience snap-back earlier around the edges because of a lower threshold voltage (Vth) and a lower drain junction breakdown voltage there, which would impair the ESD protection performance for the integrated circuit.

### SUMMARY OF THE INVENTION

In order to overcome the above problems with the prior art, the present invention provides a semiconductor device with ESD protection structure having improved ESD protection performance.

In one aspect, the present invention provides a method of making a semiconductor device with ESD protection structure, which comprises:
providing a substrate;
forming, in the substrate, at least one first trench isolation and at least one active area surrounded by the first trench isolation;
forming at least one gate over the substrate, which spans over the at least one active area and overlaps the at least one first trench isolation on both ends thereof;
forming a first mask layer over the substrate, wherein the first mask layer covers portions of the at least one gate above edges of the at least one active area; and
performing a high-dose ion implantation process using the first mask layer as a block layer, followed by an annealing process, to form, in the at least one gate, first gate portions having a first dopant concentration and a second gate portion having a second dopant concentration, wherein the first gate portions are lower portions of the at least one gate above the edges of the at least one active area, wherein the second gate portion is a remaining portion of the at least one gate other than the first gate portions, and wherein the high-dose ion implantation process also results in a source region and a drain region are formed in the at least one active area on opposite sides of the at least one gate.

In another aspect, the present invention provides a semiconductor device with ESD protection structure, which comprises:
a substrate;
at least one trench isolation formed in the substrate, wherein the trench isolation surrounds at least one first active area;
at least one gate spanning over the at least one active area and overlapping the at least one trench isolation on both ends thereof, wherein the at least one gate comprises first gate portions having a first dopant concentration and a second gate portion having a second dopant concentration, wherein the first gate portions are lower portions of the at least one gate above the edges of the at least one active area, and wherein the second gate portion is a remaining portion of the at least one gate other than the first gate portions; and
a source region and a drain region, which are formed in the at least one active area on opposite sides of the at least one gate, wherein each of the at least one gate and the source region is coupled to a first node, and wherein the drain region is coupled to a second node.

In the semiconductor device with ESD protection structure and method of the present invention, the gate and the source and drain regions on opposite sides thereof constitute a discharging MOSFET, and the gate includes the first gate portions having the first dopant concentration and the second gate portion having the second dopant concentration. The first dopant concentration is lower than the second dopant concentration. The first gate portions are lower portions of the gate above the edges of the active area, and the second gate portion is the remaining portion of the gate other than the first gate portions. The first gate portions will turn into depleted polysilicon regions under the action of an electrical field, which can increase a threshold voltage (Vth) of the discharging MOSFET, delay the occurrence of snap-back and decrease an ESD current at the edges of the active area, thereby avoiding current crowding and possible damage to the discharging MOSFET. This helps improve ESD protection performance.

### BRIEF DESCRIPTION OF THE DRAWINGS

FIG. 1 is a schematic diagram of an integrated circuit employing a discharging MOSFET for ESD protection.

FIG. 2 is a schematic cross-sectional view of a discharging MOSFET for use in the integrated circuit of FIG. 1.

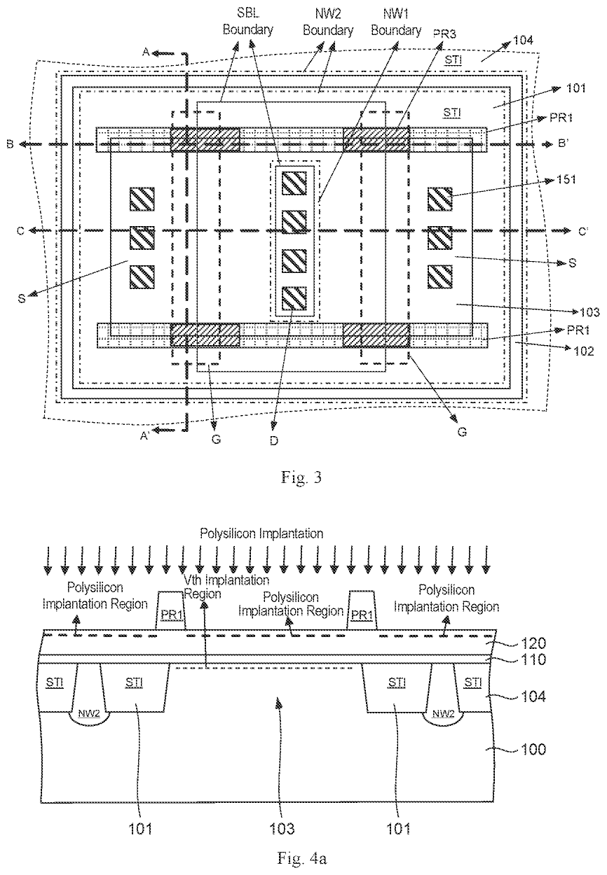

FIG. 3 is a schematic plan view of a semiconductor device with ESD protection structure according to an embodiment of the present invention.

FIGS. 4a, 4b and 4c are schematic cross-sectional views taken along lines A-A′, B-B′ and C-C′ of FIG. 3, respectively, showing selective ion implantation performed on a polysilicon layer in a method of making a semiconductor device with ESD protection structure according to an embodiment of the present invention.

FIGS. 5a, 5b and 5c are schematic cross-sectional views taken along lines A-A′, B-B′ and C-C′ of FIG. 3, respectively, showing activation of implanted ions in a method of making a semiconductor device with ESD protection structure according to an embodiment of the present invention.

FIGS. 6a, 6b and 6c are schematic cross-sectional views taken along lines A-A′, B-B′ and C-C′ of FIG. 3, respectively, showing etching of a polysilicon layer in a method of making a semiconductor device with ESD protection structure according to an embodiment of the present invention.

FIGS. 7a, 7b and 7c are schematic cross-sectional views taken along lines A-A′, B-B′ and C-C′ of FIG. 3, respectively, showing N+ ion implantation in a method of making a semiconductor device with ESD protection structure according to an embodiment of the present invention.

FIGS. 8a, 8b and 8c are schematic cross-sectional views taken along lines A-A′, B-B′ and C-C′ of FIG. 3, respectively, showing the formation of gates, source regions and drain regions in discharging MOSFETs and of a silicide blocking layer in a method of making a semiconductor device with ESD protection structure according to an embodiment of the present invention.

FIGS. 9a, 9b and 9c are schematic cross-sectional views taken along lines A-A′, B-B′ and C-C′ of FIG. 3, respectively, showing the formation of self-aligned silicide layers and source and drain lines for discharging MOSFETs in a method of making a semiconductor device with ESD protection structure according to an embodiment of the present invention.

### DETAILED DESCRIPTION

The proposed semiconductor device with ESD protection structure and method will be described in greater detail below by way of specific embodiments with reference to the accompanying drawings. It is to be understood that the figures are provided in a very simplified form not necessarily drawn to exact scale for the only purpose of facilitating easy and clear description of the embodiments. Additionally, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

In existing discharging MOSFETs used for ESD protection, edges of an active area under a gate is associated with a lower threshold voltage (Vth) and a lower drain junction breakdown voltage, leading to a higher ESD current and earlier occurrence of snap-back. This tends to cause damage to the discharging MOSFET and impair the ESD protection performance. In contrast, a semiconductor device with ESD protection structure according to embodiments described herein has an increased threshold voltage at edges of an active area, which results in greater drain-side parasitic resistance, a higher drain junction breakdown voltage and reduced parasitic gain. As a result, the occurrence of snap-back is suppressed at the edges of the active area and a current there is reduced. This lowers the risk of damage and helps improve ESD protection performance. In addition, the semiconductor device with ESD protection structure is simple in structure and well compatible with CMOS processes.

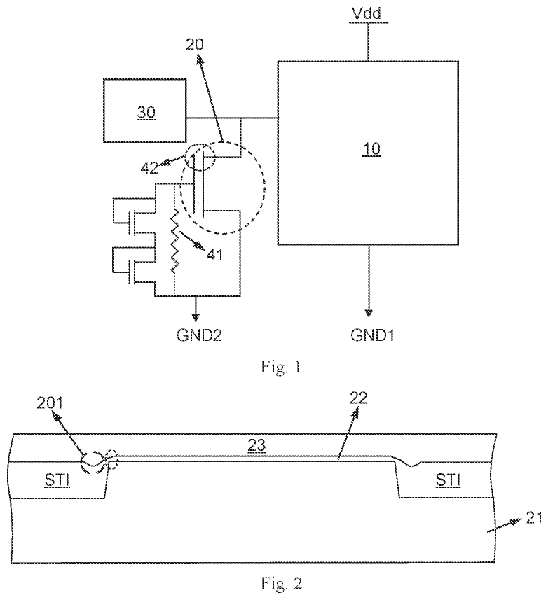

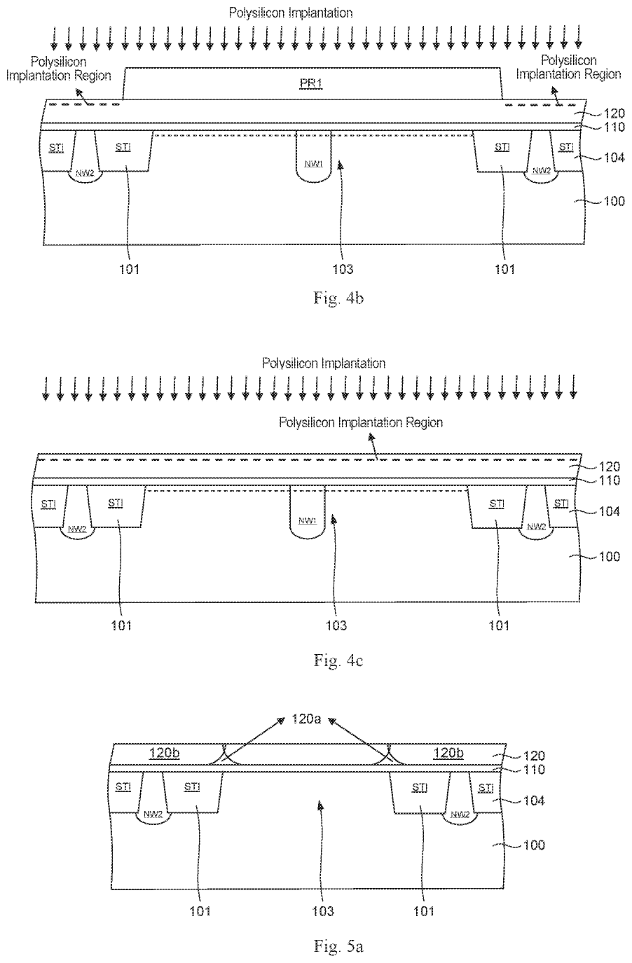

An embodiment of the present invention relates to a method of making a semiconductor device with ESD protection structure. Referring to FIG. 3, the semiconductor device with ESD protection structure can be formed on a substrate using a CMOS process. In the substrate, for example, there are formed a trench isolation (e.g., STI) 101, a guard ring 102 surrounding the trench isolation 101 and an active area 103 surrounded by the trench isolation 101. The active area 103 may be formed therein with one or more discharging MOSFETs. For example, two mirrored discharging MOSFETs can be suitably formed in the active area 103, each of the discharging MOSFETs can be used in an integrated circuit as shown in FIG. 1 to achieve ESD protection. Each discharging MOSFET includes: a source region S and a drain region D, both to be formed in the active area 103; and a gate G to be formed over the active area 103. In FIG. 3, line A-A′ is drawn in a lengthwise direction of a channel region between the source region S and the drain region D, B-B′ in a widthwise direction of the channel region along an edge of the active area 103, and C-C′ in the widthwise direction of the channel region but not along an edge of the active area 103. It is to be noted that the semiconductor device with ESD protection structure of the present invention is not limited to the configuration shown in FIG. 3. For example, in some other embodiments, one, three or more discharging MOSFETs can be suitably formed in the active area 103.

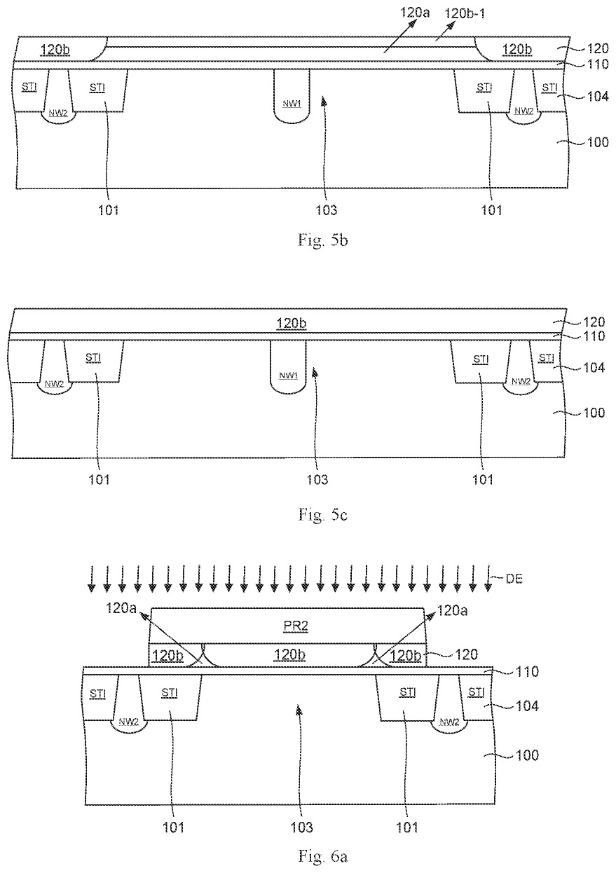

FIGS. 4a, 4b and 4c are schematic cross-sectional views taken along lines A-A′, B-B′ and C-C′ of FIG. 3, respectively, showing selective ion implantation performed on a polysilicon layer in a method of making a semiconductor device with ESD protection structure according to an embodiment of the present invention. The polysilicon layer is to be processed to form gates G of the discharging MOSFETs. Referring to FIGS. 3, 4a, 4b and 4c, according to this embodiment, the method may include the following steps before the gates G of the discharging MOSFETs are formed.

A substrate 100 is provided, and a trench isolation 101 and an active area 103 surrounded by the trench isolation 101 are formed in the substrate 100. Optionally, after the trench isolation 101 and the active area 103 are formed, a first N-well (NW1) may be formed by ion implantation in a portion of the active area 103 where a drain region of the discharging MOSFETs is to be formed. In addition, another trench isolation 104 may be formed around an outer side of the trench isolation 101, a protective area (that is another active area) is delimited between the trench isolations 101 and 104. The protective area may form a guard ring 102. At the same time as the first N-well is formed, a second N-well (NW2) may be formed in the protective area.

Next, a gate dielectric layer 110 is formed over a surface of the substrate 100. The gate dielectric layer 110 may include, for example, at least one of dielectric materials such as SiO₂, SiON and HfO. The gate dielectric layer 110 may have a thickness that is the same as that obtained from a conventional CMOS logic process, and ion implantation may follow for threshold voltage (Vth) modification (“Vth Implantation Region” in FIG. 4a). The dopant implanted may be, for example, boron (B) or boron difluoride (BF₂), and the implantation may be carried out with energy of, for example, 10 KeV to 20 KeV, at a dose of, for example, 1E12/cm² to 1E13/cm². Rapid thermal annealing or furnace annealing may be then performed to activate the implanted ions.

Subsequently, a polysilicon layer 120 is formed on the gate dielectric layer 110. The polysilicon layer 120 may have a thickness that is the same as that obtained from a conventional CMOS logic process, such as for example, about 100 nm to 500 nm. At this point, the polysilicon layer 120 is undoped, for example.

Afterwards, a mask layer PR1 (e.g., patterned photoresist) is formed on the polysilicon layer 120, wherein the mask layer PR1 covers the portions of polysilicon layer 120 located above edges of the active area 103. The mask layer PR1 also covers the subsequently-formed gates above the edges of the active area 103.

Next, with the mask layer PR1 serving as an ion implantation block layer, N-type ions such as phosphorus ions are implanted into the polysilicon layer (“Polysilicon Implantation” in FIG. 4a) with energy of, for example, 40 KeV to 80 KeV at a dose of, for example, 5E14/cm² to 5E15/cm². The N-type ions are implanted to a depth, which is, for example, smaller than the thickness of the polysilicon layer 120 (“Polysilicon Implantation Region” in FIG. 4a).

In the above process, the substrate 100 may be any substrate known to those skilled in the art for supporting components of a semiconductor integrated circuit, such as a silicon substrate, a germanium (Ge) substrate, silicon germanium substrate, silicon-on-insulator (SOI) substrate, a germanium-on-insulator (GOI) substrate or the like. In this embodiment, the substrate 100 is, for example, a P-type silicon substrate. Both the trench isolations 101, 104 may be, for example, shallow trench isolation (STI). The implantation of the N-type ions into the polysilicon layer 120 is, for example, a doping implantation process, as a result of which a doped region is formed in the polysilicon layer 120. However, this ion implantation process is not mandatory according to the present invention. For example, in an alternative embodiment, an N+ ion implantation process may be subsequently performed on the polysilicon layer at a dose and energy level, which are sufficiently high to make said ion implantation process unnecessary.

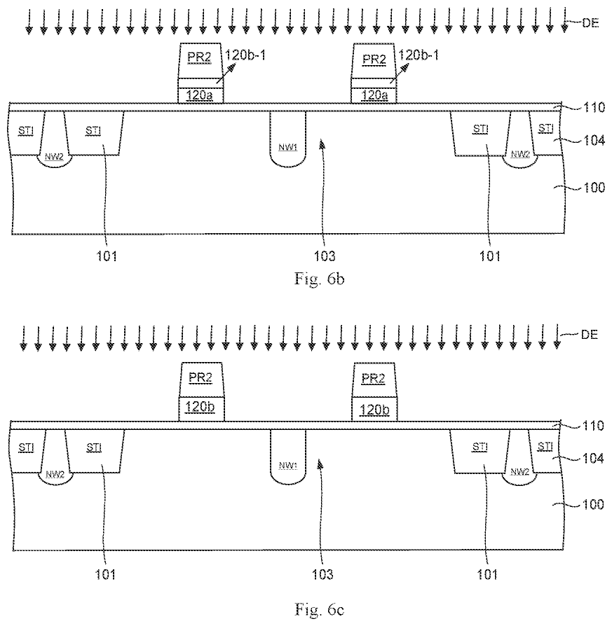

FIGS. 5a, 5b and 5c are schematic cross-sectional views taken along lines A-A′, B-B′ and C-C′ of FIG. 3, respectively, showing activation of the implanted ions in the method according to an embodiment of the present invention. Referring to FIGS. 3, 5a, 5b and 5c, according to this embodiment, the mask layer PR1 is removed, and rapid thermal annealing or furnace annealing is then performed to drive in or activate the implanted ions. During the drive-in process, the N-type ions implanted into the polysilicon layer 120 diffuse, for example, vertically to the bottom of the polysilicon layer 120 and laterally to the portions that were previously covered by the mask layer PR1. As N-type ions could not diffuse into bottom parts of the portions that were previously covered by the mask layer PR1, they have a relatively low dopant concentration, or even remain undoped, for example. After the annealing process is complete, as shown in FIGS. 5a, 5b and 5c, first dopant concentration regions 120a and second dopant concentration regions 120b are formed in the polysilicon layer 120. The first dopant concentration regions 120a have an N-type dopant concentration that is lower than an N-type dopant concentration of the second dopant concentration regions 120b, or the first dopant concentration regions 120a are, for example, undoped (i.e., the N-type dopant concentration thereof is zero). The first dopant concentration regions 120a cover boundaries of the trench isolation 101 and the active area 103. The first dopant concentration regions 120a are bottom parts of portions of the polysilicon layer 120 above the aforesaid edges of the active area 103, and the second dopant concentration regions 120b surround the first dopant concentration regions 120a. In this embodiment, in the second dopant concentration regions 120b, at least portions 120b-1 located on the first dopant concentration regions 120a are N-type doped.

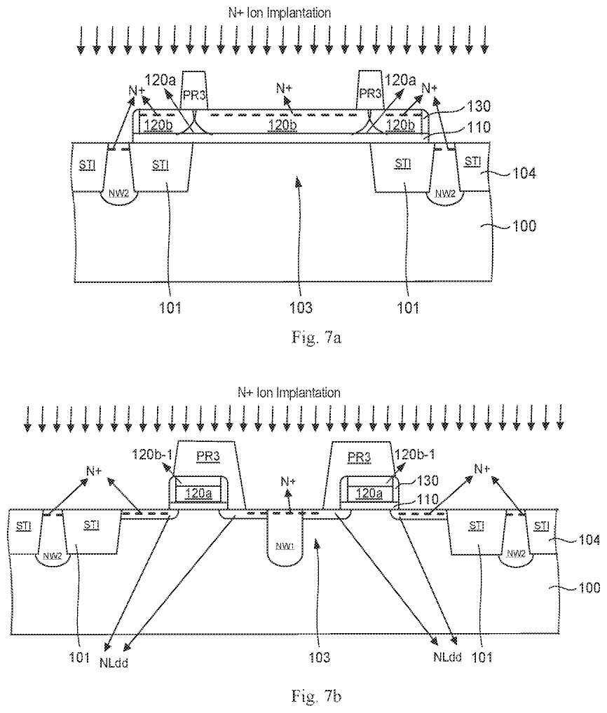

FIGS. 6a, 6b and 6c are schematic cross-sectional views taken along lines A-A′, B-B′ and C-C′ of FIG. 3, respectively, showing etching of the polysilicon layer in the method according to an embodiment of the present invention. Referring to FIGS. 3, 6a, 6b and 6c, according to this embodiment, a mask layer PR2 (e.g., patterned photoresist) is formed on the polysilicon layer 120 to define regions where gates of the discharging MOSFETs are to be formed. Subsequently, with the mask layer PR2 serving as an etch block layer, an anisotropic dry etching process DE is carried out to remove the polysilicon layer 120 exposed from the mask layer PR2, with the remaining portions of the polysilicon layer 120 serving as the gates. The mask layer PR2 is then removed.

As shown in FIGS. 6a, 6b and 6c, as a result of the above process, the remaining portions of the polysilicon layer 120 span across the active area 103 in the direction of line A-A′, with opposite ends thereof located on (or overlapping) the trench isolation 101. Moreover, the remaining portions of the polysilicon layer 120 traverse over the boundaries of the active area 103 and the trench isolation 101 covered by the first dopant concentration regions 120a.

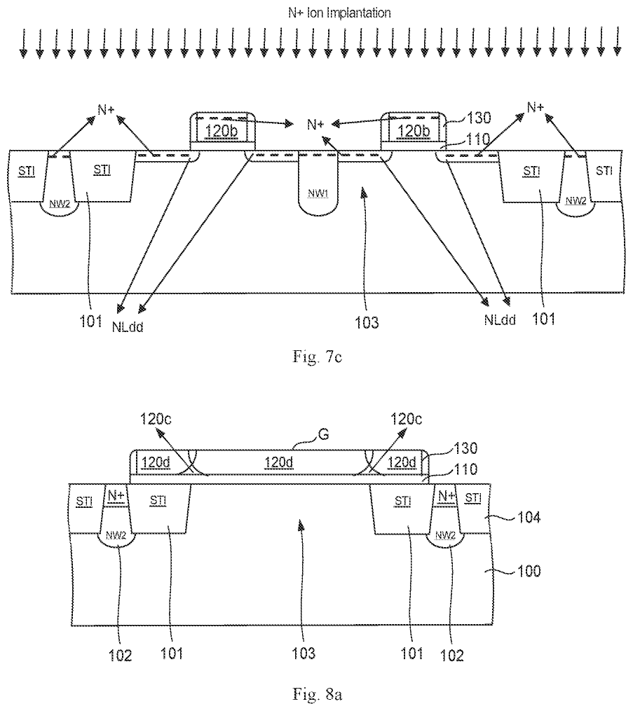

FIGS. 7a, 7b and 7c are schematic cross-sectional views schematic cross-sectional views taken along lines A-A′, B-B′ and C-C′ of FIG. 3, respectively, showing N+ ion implantation in the method according to an embodiment of the present invention. Referring to FIGS. 3, 7a, 7b and 7c, according to this embodiment, the active area 103 then undergoes implantation of N-type ions and heat treatment. As a result, NLdd regions adjacent to and connected with the source regions S and the drain region D of the discharging MOSFETs are formed in the active area 103. Subsequently, a spacer process is carried out to form spacers 130 on sidewalls of the polysilicon layer 120, and a mask layer PR3 (e.g., patterned photoresist) is formed over the substrate 100. The mask layer PR3 covers a top surface of a portion of the polysilicon layer 120 above the edges of the active area 103, and extends from the side of the polysilicon layer 120 away from the trench isolation 101 and covers portions of the active area 103 (i.e., portions of the NLdd regions on the side of the drain region). Subsequently, with the mask layer PR3 serving as a block layer, an N+ ion implantation process is carried out, in which, for example, arsenic (As) is implanted with energy of, for example, 20 KeV to 80 KeV, at a dose of, for example, 1E15/cm² to 1E16/cm². After that, the mask layer PR3 is removed.

As shown in FIGS. 7a, 7b and 7c, during the N+ ion implantation process, a surface of the protective area in which the guard ring 102 is to be formed, top surfaces of portions of the polysilicon layer 120 not above the edges of the active area 103 and surfaces of portions of the active area 103 beside the polysilicon layer 120 are exposed from the mask layer PR3. Therefore, as a result of the N+ ion implantation process, the surface of the protective area in which the guard ring 102 is to be formed, upper portions of the portions of the polysilicon layer 120 not above the edges of the active area 103 and upper portions of the portions of the active area 103 beside the polysilicon layer 120 are all heavily N-type doped (N+). Moreover, since the mask layer PR3 above the edges of the active area 103 extends from the side of the polysilicon layer 120 away from the trench isolation 101 and covers the portions of the active area 103, among the resulting heavily N-type doped regions, those formed in the upper portions of the active area 103 around the edges and on the side of the polysilicon layer 120 away from the trench isolation 101 are spaced from the adjacent spacers 130 by a certain distance, and the NLdd regions formed on the side of the polysilicon layer 120 away from the trench isolation 101 are connected with and adjacent to these heavily N-type doped regions and extend to a position under the gate dielectric layer 110.

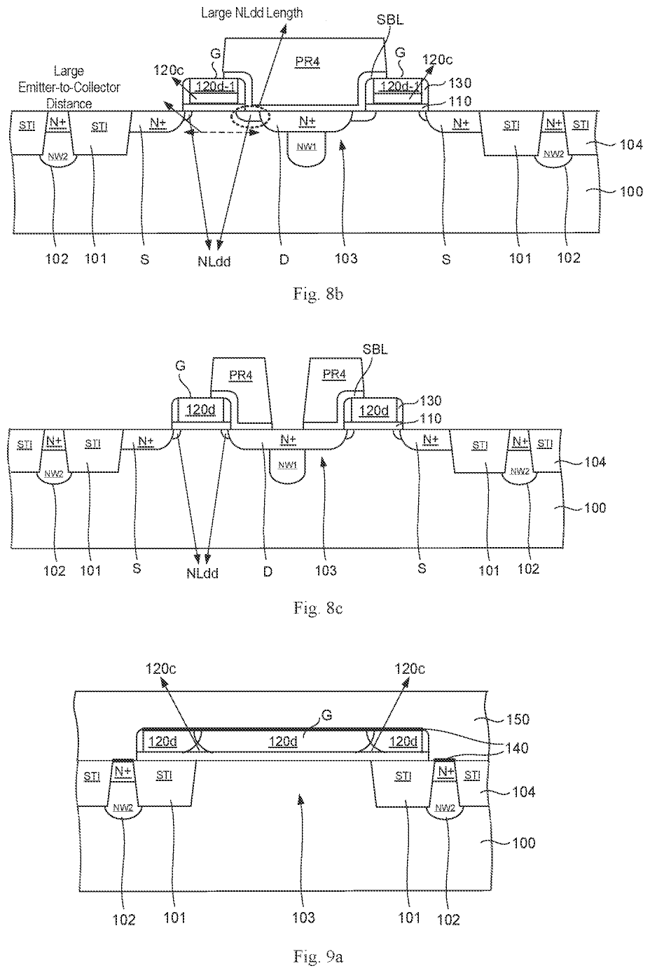

FIGS. 8a, 8b and 8c are schematic cross-sectional views taken along lines A-A′, B-B′ and C-C′ of FIG. 3, respectively, showing the formation of the gates, source regions and drain region in the discharging MOSFETs and of a silicide blocking layer in the method according to an embodiment of the present invention. Referring to FIGS. 3, 8a, 8b and 8c, according to this embodiment, after the aforementioned N+ ion implantation process is complete, rapid thermal annealing or furnace annealing is carried out to form an N+ doped guard ring 102 in the protective area intended for this purpose. The polysilicon layer 120 forms the gates of the discharging MOSFETs. The top portions of the active area 103 on the side of the gates G proximal to the trench isolation 101 form first source/drain regions (e.g., the source regions S) of the discharging MOSFETs, and the top portions of the active area 103 on the side of the gates G away from the trench isolation 101 form second source/drain regions of the discharging MOSFETs (e.g., the drain region D). Moreover, portions of the drain region D around the edges of the active area 103 are spaced apart from the adjacent spacers 130 by a certain distance, and the NLdd regions on the side of the drain region D are connected with and adjacent to the drain region D and extend to a position under the gate dielectric layer 110.

In the annealing process, the N-type ions implanted into the upper portions of the polysilicon layer 120 on both sides of the boundary of the active area 103 and the trench isolation 101 diffuse, for example, vertically to the bottom of the gate and laterally to portions of the gate that were previously covered by the mask layer PR3. As a result of the diffusion, ions migrate into the portions that were previously covered by the mask layer PR3 from both sides thereof, lowering boundaries of the first dopant concentration regions 120a and the second dopant concentration regions 120b in the gate. Finally, first gate portions 120c having a first dopant concentration and second gate portions 120d having a second dopant concentration (as shown in FIG. 8b, a part of the second gate portions (120d-1) located above the first gate portions is formed by: ions implanted by the high-dose ion implantation process diffuse to the gate covered by the mask layer PR3 by the annealing process) are formed in the polysilicon layer 120. The first dopant concentration is lower than the second dopant concentration, or the first gate portions 120c are undoped. The first gate portions 120c cover the edges of the active area 103. The second gate portions 120d are the remaining portions of the gate G other than the first gate portions 120c, and the concentration of the N-type dopant ions therein is higher than 0 (e.g., they are heavily N-type doped).

As shown in FIGS. 3, 8b and 8c, in order to form self-aligned silicide layers, which can decrease contact resistance of the guard ring 102, the gates G, the source regions S and the drain region D, as well as resistance of the guard ring 102, the gates G and the source regions of the discharging MOSFETs, the silicide blocking layer SBL is formed over the substrate 100. This may include: depositing a silicide blocking layer SBL over the substrate 100 without using a mask, which may be silicon oxide, silicon nitride or the like and may have a thickness of, for example, 10 nm to 50 nm; subsequently, forming a mask layer PR4 covering a part of the silicide blocking layer SBL, removing the remaining uncovered portion of the silicide blocking layer SBL by wet or dry etching and removing the mask layer PR4; and then performing a metal salicide process. In this embodiment, the silicide blocking layer SBL covers parts of the top surfaces of the gates G in the discharging MOSFETs, the spacers 130 on the side of the gates G proximate the drain region, surfaces of the NLdd regions adjacent to the spacers 130 and a part of a surface of the drain region D. The surface of the drain region D around the edges of the active area 103 is totally covered by the silicide blocking layer SBL. An opening is formed in the silicide blocking layer SBL above the surface of the drain region D away from the edges of the active area 103 and the gates G. In this way, a portion of the drain region D away from the edges of the active area 103 and the gates G is exposed in the opening, within which the drain contacts are formed with the later process steps.

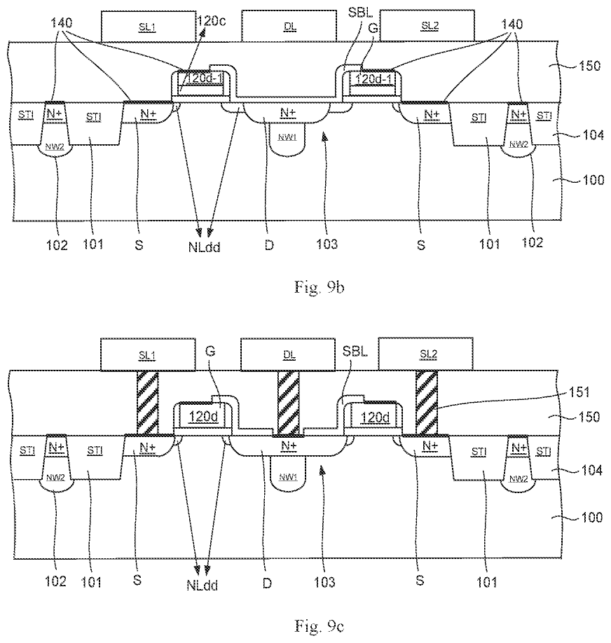

FIGS. 9a, 9b and 9c are schematic cross-sectional views taken along lines A-A′, B-B′ and C-C′ of FIG. 3, respectively, showing the formation of self-aligned silicide layers and source and drain lines for the discharging MOSFETs in the method according to an embodiment of the present invention. Referring to FIGS. 3, 9a, 9b and 9c, according to this embodiment, the mask layer PR4 is removed, and under the protection of the silicide blocking layer SBL, a salicide process is performed to create self-aligned silicide layers 140 on the surfaces of the guard ring 102, the parts of the gates G of the discharging MOSFETs, the source regions S and the portion of the drain region D exposed in the opening in the silicide blocking layer SBL. Subsequently, an interlayer dielectric layer 150 covering the discharging MOSFETs and vias 151 in the interlayer dielectric layer 150 for contacting to the source regions S and the drain region D are formed. After that, a metal layer is formed on a surface of the interlayer dielectric layer 150 and etched into source lines connecting the respective source regions S (e.g., source lines SL1 and SL2 belonging to the respective discharging MOSFETs) and a drain line DL (e.g., shared by the two discharging MOSFETs).

The semiconductor device with ESD protection structure made with the above-described method can be used in an integrated circuit. It includes the discharging MOSFETs, and the polysilicon layer 120 serves as the gates of the discharging MOSFETs. The method has the benefits as follows (with reference to FIG. 8b):

First, the gates G includes the first gate portions 120c having a relatively low dopant concentration and the second gate portions 120d having a relatively high dopant concentration. The first gate portions 120c are lower portions of the gates G located above the edges of the active area 103, and the second gate portions 120d are the remaining portions of the gates G other than the first gate portions 120c. The first gate portions 120c will turn into depleted polysilicon regions under the action of an electrical field, which can increase a threshold voltage (Vth) of the discharging MOSFETs, delay the occurrence of snap-back and decrease an ESD current at the edges of the active area 103, thereby avoiding current crowding and possible damage to the discharging MOSFETs.

Second, since the NLdd regions on the side of the drain region D are relatively long, higher drain-side parasitic resistance can be obtained, which increases a drain junction breakdown voltage in parasitic transistors of the discharging MOSFETs and delays the occurrence of snap-back at the edges of the active area 103. As a result, snap-back is expected to occur to the active area 103, except the edges, almost independently of location, resulting in improved ESD protection performance.

Third, at the edges of the active area 103, since the drain region D of the discharging MOSFETs is spaced from the spacers 130 on the side of the gates G proximate the drain region D by certain distances, the distances from the source regions S to the drain region D are enlarged. This is equivalent to increased emitter-to-collector distances of the parasitic transistors, which can reduce current gain at the edges of the active area 103 and helps decrease an ESD current there, thus avoiding current crowding and possible damage to the discharging MOSFETs. Further, the method can be implemented by conventional CMOS processes and is thus low in cost.

Referring to FIGS. 3, 9a, 9b and 9c, embodiments of the present invention relate to a semiconductor device with ESD protection structure, comprising:
a substrate 100;
a trench isolation 101, which is formed in the substrate 100 and surrounds an active area 103, wherein the trench isolation 101 is, for example, a shallow trench isolation (STI);
a polysilicon gate G spanning over the active area 103 and overlaps the trench isolation 101 at both ends thereof, the gate G comprising first gate portions 120c having a first dopant concentration and a second gate portion 120d having a second dopant concentration, the first dopant concentration being lower than the second dopant concentration, the first gate portions 120c being lower portions of the gates G located above edges of the active area 103, the second gate portion 120d being the remaining portion of the gate other than the first gate portions; and
a source region S and a drain region D, which are formed in the active area 103 on opposite sides of the gate G, wherein the gate G and the source region S are both coupled to a first node, and the drain region D is coupled to a second node.

In the semiconductor device with ESD protection structure, the gate G, the source region S and the drain region D constitute a discharging MOSFET, in which the dopant ion concentration of the first gate portions 120c of the gate G located above the edges of the active area 103 is lower than the dopant ion concentration of the rest of the gate, or the first gate portion is undoped. The first gate portions 120c will turn into depleted polysilicon regions under the action of an electrical field, which can increase a threshold voltage (Vth) of the discharging MOSFET, delay the occurrence of snap-back and decrease an ESD current at the edges of the active area 103, thereby avoiding current crowding and possible damage to the discharging MOSFET.

The discharging MOSFET can be used in an integrated circuit as shown in FIG. 1. In this case, the first node corresponds to the ground node and the second node to a pad to be protected, such as the I/O pad, power supply (Vdd) pads. During operation of the integrated circuit, when high ESD voltage is created on the drain side of the discharging MOSFET due to accumulation of electrostatic charges, a parasitic bipolar junction transistor of the discharging MOSFET is turned on to quickly discharge the ESD voltage or current to the ground. As a result, the ESD voltage will drop rapidly, and the electrostatic charges will not enter and possibly damage the internal circuit. That is, the parasitic transistor exhibits a snap-back property.

The semiconductor device with ESD protection structure may further comprise another trench isolation 104 which is located at an outer side of the trench isolation 101, and a protective area is formed between these two trench isolations 101 and 104. In the other active area, an N+ doped region that surrounds the trench isolation 101 and the active area 103 is formed by N+ ion implantation and serves as a guard ring 102. In the active area 103, a first N-well (NW1) may be formed underneath the drain contact, and in the other active area, a second N-well (NW2) may be optionally formed under the guard ring 102. The semiconductor device with ESD protection structure may further comprise spacers 130 on sidewalls of the gate G, a gate dielectric layer 110 between the gate G and the substrate 100 and self-aligned silicide layers 140 respectively on top surfaces of the gate G, the source region S, the drain region D and the guard ring 102.

In some embodiments, the discharging MOSFET is for example an NMOSFET. In this case, the gate G, the source region S and the drain region D are all N-type doped. Optionally, two mirrored discharging MOSFETs sharing with a common drain region D may be formed in the active area 103. The semiconductor device with ESD protection structure may further comprise an interlayer dielectric layer 150 over the substrate 100, vias 151 extending through the interlayer dielectric layer 150 and source SL1, SL2 and drain DL lines on a surface of the interlayer dielectric layer 150. In other embodiments, the discharging MOSFET may alternatively be a PMOSFET.

The semiconductor device with ESD protection structure may further comprise a source-side NLdd region and a drain-side NLdd region. The source-side NLdd region is formed on the side of the source region S proximate the drain region D and is connected with and adjacent to the source region S, and extends to a position under the gate dielectric layer 110. The drain-side NLdd region is formed on the side of the drain region D proximate the source region S and is connected with and adjacent to the drain region D, and extends to a position under the gate dielectric layer 110.

Optionally, at the edges of the active area 103, the drain region D may be spaced apart from adjacent spacer 130 on the sidewall of the gate G by a distance, and the drain-side NLdd region may extend from a position under the gate dielectric layer 110 to a position out of this spacer 130, and connect the drain region D. In this case, compared to the prior art, a distance between the source region S and the drain region D is enlarged at the edges of the active area 103, and the drain-side NLdd region has an increased length. In this way, a corresponding emitter-to-collector distance of the parasitic transistor is increased. This reduces BJT current gain and helps decrease an ESD current at the edges of the active area 103, thus avoiding current crowding and possible damage to the discharging MOSFETs. Moreover, the longer drain-side NLdd region imparts greater drain-side parasitic resistance, which increases a drain junction breakdown voltage of the parasitic transistor and delays the occurrence of snap-back at the edges of the active area 103. As a result, snap-back is expected to occur to the active area 103 almost independently of location, helping in improving the ESD protection performance of the discharging MOSFET.

Although the above method and semiconductor device with ESD protection structure have been described in the exemplary context of the discharging MOSFET being implemented as an NMOSFET, they can be equally applicable to the case where the discharging MOSFET is a PMOSFET after being appropriately modified according to differences between the PMOSFET and NMOSFET.

It is to be noted that the embodiments disclosed herein are described in a progressive manner. As the device embodiments correspond to the method embodiments, they are described relatively briefly, and reference can be made to the description of the method embodiments for any details of interest in them.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A method of making a semiconductor device with ESD protection structure, comprising:
providing a substrate;
forming, in the substrate, at least one first trench isolation and at least one active area surrounded by the at least one first trench isolation;
forming at least one gate over the substrate, wherein the at least one gate spans over the at least one active area and overlaps the at least one first trench isolation on both ends thereof;
forming a first mask layer over the substrate, wherein the first mask layer covers portions of the at least one gate located above edges of the at least one active area; and
performing a high-dose ion implantation process using the first mask layer as a block layer, followed by an annealing process, to form, in the at least one gate, first gate portions having a first dopant concentration and a second gate portion having a second dopant concentration, wherein the first gate portions are lower portions of the at least one gate located above the edges of the at least one active area, wherein the second gate portion is a remaining portion of the at least one gate other than the first gate portions, and wherein the high-dose ion implantation process also results in a source region and a drain region are formed in the at least one active area on opposite sides of the at least one gate.

2. The method of claim 1, wherein the first dopant concentration is lower than the second dopant concentration, or wherein the first gate portion is undoped.

3. The method of claim 1, wherein ions implanted by the high-dose ion implantation process diffuse to the at least one gate covered by the first mask layer by the annealing process, to form a part of the second gate portion located above the first gate portion.

4. The method of claim 1, further comprising, before the high-dose ion implantation process:
forming NLdd regions in the at least one active area on opposite sides of the at least one gate, wherein each NLdd region extends to a position under a gate dielectric layer.

5. The method of claim 3, wherein the first mask layer covers top surfaces of the portions of the at least one gate at the edges of the at least one active area and extends along a side of the at least one gate away from the at least one first trench isolation and covers a portion of the at least one active area.

6. The method of claim 1, wherein forming the at least one gate over the substrate comprises:
forming a gate dielectric layer and a polysilicon layer over the substrate;
forming a second mask layer on the polysilicon layer, wherein the second mask layer covers portions of the polysilicon layer located above the edges of the at least one active area;
performing an N-type ion implantation process using the second mask layer as a block layer and followed by an annealing process, to form, in the polysilicon layer, first dopant concentration regions and a second dopant concentration region, wherein each of the first dopant concentration regions has an N-type dopant concentration lower than an N-type dopant concentration of the second dopant concentration region, wherein the first dopant concentration regions correspond to lower portions of the polysilicon layer located above the edges of the at least one active area, wherein the second dopant concentration region surrounds the first dopant concentration regions;
forming the at least one gate by etching the polysilicon layer; and
forming spacers on opposite sides of the at least one gate.

7. The method of claim 1, further comprising, before the at least one gate is formed over the substrate:
forming at least one second trench isolation in the substrate, wherein at least one protective area is delimited by the first and second trench isolations,
wherein the high-dose ion implantation process also results in a guard ring formed in an upper portion of the at least one protective area.

8. The method of claim 7, further comprising:
forming a first N-well in the at least one active area underneath a predefined drain contact area; and/or forming a second N-well in the at least one protective area.

9. A semiconductor device with ESD protection structure, comprising:
a substrate;
at least one first trench isolation formed in the substrate, wherein the at least one first trench isolation surrounds at least one active area;
at least one gate spanning over the at least one active area and overlapping the at least one first trench isolation on both ends thereof, wherein the at least one gate comprises first gate portions having a first dopant concentration and a second gate portion having a second dopant concentration, wherein the first gate portions are lower portions of the at least one gate located above the edges of the at least one active area, and wherein the second gate portion is a remaining portion of the at least one gate other than the first gate portion; and
a source region and a drain region, which are formed in the at least one active area on opposite sides of the at least one gate, wherein the at least one gate and the source region are coupled to a first node, and wherein the drain region is coupled to a second node.

10. The semiconductor device with ESD protection structure of claim 9, wherein the first dopant concentration is lower than the second dopant concentration, or wherein the first gate portion is undoped.

11. The semiconductor device with ESD protection structure of claim 9, wherein the at least one gate, the source region and the drain region constitute a discharging MOSFET, and wherein the first node is a ground node, and the second node is connected to a pad to be protected.

12. The semiconductor device with ESD protection structure of claim 11, wherein two discharging MOSFETs that are mirrored are formed in the at least one active area.

13. The semiconductor device with ESD protection structure of claim 9, further comprising:
a gate dielectric layer formed between the at least one gate and the substrate;
spacers covering sidewalls of the at least one gate;
a source-side NLdd region formed on a side of the source region proximate the drain region, wherein the source-side NLdd region is connected with and adjacent to the source region, and extends to a position under the gate dielectric layer; and
a drain-side NLdd region formed on a side of the drain region proximate the source region, wherein the drain-side NLdd region is connected with and adjacent to the drain region, and extends to a position under the gate dielectric layer.

14. The semiconductor device with ESD protection structure of claim 13, wherein the drain region is spaced apart from one of the spacers proximate the drain by a distance, and wherein the drain-side NLdd region extends from a position under the gate dielectric layer to a position out of the corresponding spacer, and connects the drain region.

15. The semiconductor device with ESD protection structure of claim 9, further comprising:
a guard ring located in at least one protective area that is located at an outer side of the first trench isolation, wherein the guard ring is N-type doped and surrounds the at least one first trench isolation.

16. The semiconductor device with ESD protection structure of claim 15, wherein: a first N-well is located in the at least one active area underneath a predefined drain contact area; and/or a second N-well is located in the at least one protective area.
